(19) United States
(12) Patent Application Publication
(10) Pub. No.: US 2025/0350386 A1
(43) Pub. Date: Nov. 13, 2025

(54) COMMUNICATION QUALITY CALCULATION METHOD, COMMUNICATION QUALITY CALCULATION APPARATUS, AND PROGRAM

(71) Applicant: NEC Corporation, Minato-ku, Tokyo (JP)

(72) Inventor: Yoshiaki NISHIKAWA, Tokyo (JP)

(73) Assignee: NEC Corporation, Minato-ku, Tokyo (JP)

(21) Appl. No.: 18/871,523

(22) PCT Filed: Jun. 30, 2022
(86) PCT No.: PCT/JP2022/026364

§ 371 Date: Dec. 4, 2024

(51) Int. Cl. H04B 17/391; G01R 29/08; H04B 17/23

(52) U.S. Cl. CPC H04B 17/3913; G01R 29/0892; H04B 17/23; H04B 17/3911

(57) ABSTRACT

A communication quality calculation apparatus of the present disclosure includes: an acquiring unit that acquires a spatial map having a plurality of regions obtained by dividing a target space in which a mobile object will move by a size corresponding to a movement speed of the mobile object; a spectrum calculating unit that generates a spectrum representing electric power for each frequency of received radio waves in each of the regions within the spatial map based on preset information; and a variation calculating unit that calculates, based on a change in the spectrum between the regions within the spatial map, a degree of variation in communication quality between the regions.

### TECHNICAL FIELD

The present invention relates to a communication quality calculation method, a communication quality calculation apparatus, and a program.

### BACKGROUND ART

In recent years, various mobile communications have been realized through development of wireless communication technology. For example, mobile objects such as an automatic guided vehicle (AGV) that conveys a package in a factory and a construction machine that works in a construction site are controlled by wireless communication. Then, in such mobile communications, high communication quality is required, so that there is a need to monitor radio wave environments.

On the other hand, a problem in communication quality in wireless communication is fading, which is a phenomenon that radio waves arriving with a time lag interfere with each other and cause variations in radio wave intensity level. For this reason, in Patent Literature 1, the feature value of a radio wave in a time section in which there is no influence of fading is extracted.

### CITATION LIST

### Patent literature

Patent Literature 1: WO2017/195842:

### SUMMARY OF INVENTION

### Technical Problem

However, the technique of Patent Literature 1 described above does not enable measurement of communication quality in a time period in which there is an influence of fading. For this reason, in mobile communications, in a time section in which there is an influence of fading, that is, when a mobile object is moving during measurement of communication quality, fading during the time cannot be predicted. As a result, there arises a problem that communication quality cannot be accurately predicted in mobile object communication control and appropriate control cannot be performed.

Accordingly, an object of the present disclosure is to provide a communication quality calculation method that can solve the abovementioned problem that communication quality cannot be accurately predicted in mobile object communication control and appropriate control cannot be performed.

### Solution to Problem

A communication quality calculation method as an aspect of the present disclosure includes: acquiring a spatial map having a plurality of regions obtained by dividing a target space in which a mobile object will move by a size corresponding to a movement speed of the mobile object; generating a spectrum representing electric power for each frequency of received radio waves in each of the regions within the spatial map based on preset information; and calculating, based on a change in the spectrum between the regions within the spatial map, a degree of variation in communication quality between the regions.

Further, a communication quality calculation method as an aspect of the present disclosure includes: calculating a degree of variation in communication quality between regions based on a change between the regions of a spectrum, the spectrum representing electric power for each frequency of received radio waves in each of the regions within a spatial map, the spatial map having a plurality of regions obtained by dividing a target space in which a mobile object will move by a size corresponding to a movement speed of the mobile object; and displaying the degree of variation on a display device.

Further, a communication quality calculation apparatus as an aspect of the present disclosure includes: an acquiring unit that acquires a spatial map having a plurality of regions obtained by dividing a target space in which a mobile object will move by a size corresponding to a movement speed of the mobile object; a spectrum calculating unit that generates a spectrum representing electric power for each frequency of received radio waves in each of the regions within the spatial map based on preset information; and a variation calculating unit that calculates, based on a change in the spectrum between the regions within the spatial map, a degree of variation in communication quality between the regions.

Further, a communication quality calculation apparatus as an aspect of the present disclosure includes: a calculating unit that calculates a degree of variation in communication quality between regions based on a change between the regions of a spectrum, the spectrum representing electric power for each frequency of received radio waves in each of the regions within a spatial map, the spatial map having a plurality of regions obtained by dividing a target space in which a mobile object will move by a size corresponding to a movement speed of the mobile object; and a display unit that displays the degree of variation on a display device.

Further, a program as an aspect of the present disclosure includes instructions for causing a computer to execute processes to: acquire a spatial map having a plurality of regions obtained by dividing a target space in which a mobile object will move by a size corresponding to a movement speed of the mobile object; generate a spectrum representing electric power for each frequency of received radio waves in each of the regions within the spatial map based on preset information; and calculate, based on a change in the spectrum between the regions within the spatial map, a degree of variation in communication quality between the regions.

### Advantageous Effects of Invention

Configured as described above, the present disclosure enables accurate prediction of communication quality in mobile object communication control and appropriate control.

### BRIEF DESCRIPTION OF DRAWINGS

FIG. 1 is a block diagram showing the overall configuration of a communication quality calculation system in a first example embodiment of the present disclosure.

FIG. 2 is a block diagram showing the configuration of the communication quality calculation apparatus disclosed in FIG. 1.

FIG. 3 is a view showing a state of processing by the communication quality calculation apparatus disclosed in FIG. 1.

FIG. 4 is a view showing a state of processing by the communication quality calculation apparatus disclosed in FIG. 1.

FIG. 5 is a view showing a state of processing by the communication quality calculation apparatus disclosed in FIG. 1.

FIG. 6 is a view showing a state of processing by the communication quality calculation apparatus disclosed in FIG. 1.

FIG. 7 is a view showing a state of processing by the communication quality calculation apparatus disclosed in FIG. 1.

FIG. 8 is a view showing a state of processing by the communication quality calculation apparatus disclosed in FIG. 1.

FIG. 9 is a view showing a state of processing by the communication quality calculation apparatus disclosed in FIG. 1.

FIG. 10 is a view showing a state of processing by the communication quality calculation apparatus disclosed in FIG. 1.

FIG. 11 is a view showing a state of processing by the communication quality calculation apparatus disclosed in FIG. 1.

FIG. 12 is a flowchart showing the operation of the communication quality calculation apparatus disclosed in FIG. 1.

FIG. 13 is a block diagram showing the hardware configuration of a communication quality calculation apparatus in a second example embodiment of the present disclosure.

FIG. 14 is a block diagram showing the configuration of the communication quality calculation apparatus in the second example embodiment of the present disclosure.

### DESCRIPTION OF EXAMPLE EMBODIMENTS

### First Example Embodiment

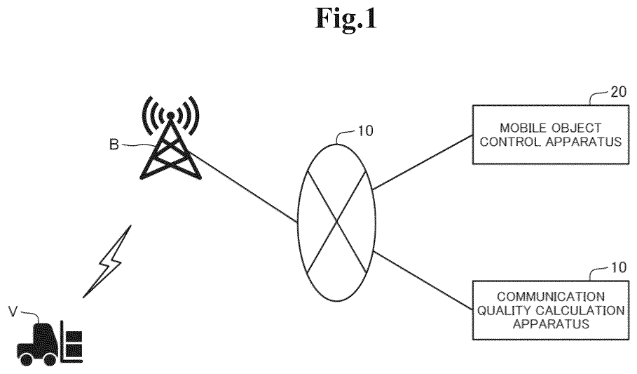

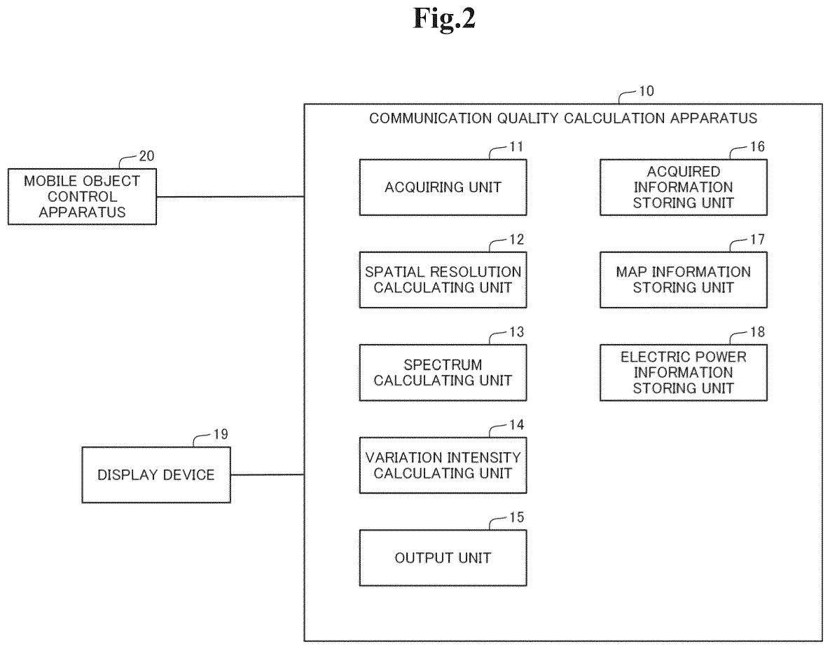

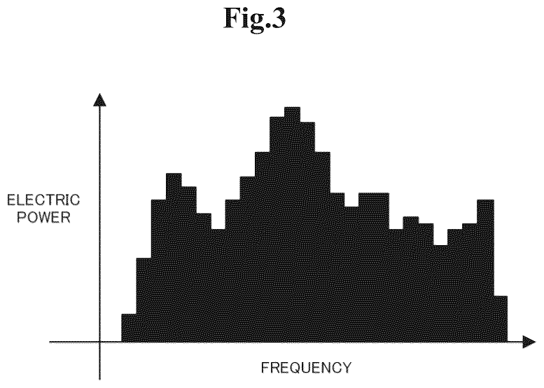

A first example embodiment of the present disclosure will be described with reference to FIGS. 1 to 12. FIGS. 1 and 2 are views for describing the configuration of a communication quality calculation system, and FIGS. 3 to 12 are views for describing the processing operation of the communication quality calculation system.

### Configuration

The communication quality calculation system in this example embodiment calculates communication quality in a space where a mobile object V is controlled by wireless communication. For example, in this example embodiment, the mobile object V is a construction machine that works in a construction site. Then, the movement route of the construction machine as the mobile object V is set in advance, and the communication quality calculation system calculates communication quality in locations related to the movement route in order to visualize the communication quality as an example. However, the mobile object V is not limited to the construction machine, and may be any mobile object such as an automatic guided vehicle (AGV) that conveys a package in a factory.

As shown in FIG. 1, the communication quality calculation system includes a communication quality calculation apparatus 10 connected to a network N. Then, the communication quality calculation apparatus 10 is connected via the network N to a mobile object control apparatus 20 that controls the abovementioned mobile object V by wireless communication, and a wireless communication apparatus B that controls wireless communication and performs transmission and reception of signals in the wireless communication.

The wireless communication apparatus B is, for example, an apparatus that performs wireless communication in 5G (5th Generation: fifth generation mobile communication system) and is, for example, a base station. Here, the wireless communication apparatus B has a function of transmitting a control signal corresponding to an instruction from the mobile object control apparatus 20 to the mobile object V and of receiving a signal emitted from the mobile object V and transmitting the signal to the mobile object control apparatus 20 by wireless communication. Moreover, as a basic function, the wireless communication apparatus B measures the communication quality in wireless communication at constant time intervals and controls the communication quality to be constant. For example, the wireless communication apparatus B measures the communication quality at intervals of several tens of ms (milliseconds). Then, the wireless communication apparatus B has a function of notifying a setting value related to wireless communication in response to a request from the communication quality calculation apparatus 10 as will be described later. For example, the wireless communication apparatus B notifies setting values such as the abovementioned communication quality measurement interval and the frame length of a frame that is a transmission signal, to the communication quality calculation apparatus 10. In addition, the wireless communication apparatus B may be a communication facility of any communication method.

The mobile object control apparatus 20 transmits a control signal to the mobile object V via the wireless communication apparatus B to control the operation of the mobile object V. For example, the mobile object control apparatus 20 controls the operation of a construction machine serving as the mobile object V so that the construction machine moves along a preset movement route and executes a task. For example, the mobile object control apparatus 20 controls the movement direction, movement speed, arm operation and so forth of the mobile object V. At this time, the mobile object control apparatus 20 also acquires a notification signal from the mobile object V and controls the operation of the mobile object V in response to the notification signal. For example, the mobile object control apparatus 20 acquires detection values detected by sensors mounted on the mobile object V, such as a movement speed and a distance to a surrounding object, and controls the operation of the mobile object V based on the detection values. Then, the mobile object control apparatus 20 has a function of notifying information on the operation of the mobile object V in response to a request from the communication quality calculation apparatus 10 as will be described later. For example, the mobile object control apparatus 20 notifies the movement route and movement speed of the mobile object V to the communication quality calculation apparatus 10. In addition, the mobile object control apparatus 20 may be an apparatus that controls any mobile object V.

The communication quality calculation apparatus 10 is configured with one or a plurality of information processing apparatuses each including an arithmetic logic unit and a memory unit. The communication quality calculation apparatus 10 may be an information processing apparatus that is managed by a business operator using the mobile object V, or may be an information processing apparatus that is managed by a business operator providing a service for measuring communication quality in a space where the mobile object V operates. Then, as shown in FIG. 2, the communication quality calculation apparatus 10 includes an acquiring unit 11, a spatial resolution calculating unit 12, a spectrum calculating unit 13, a variation intensity calculating unit 14, and an output unit 15. The respective functions of the acquiring unit 11, the spatial resolution calculating unit 12, the spectrum calculating unit 13, the variation intensity calculating unit 14, and the output unit 15 can be realized by the arithmetic logic unit executing a program for realizing the respective functions stored in the memory unit. The communication quality calculation apparatus 10 also includes an acquired information storing unit 16, a map information storing unit 17, and an electric power information storing unit 18. The acquired information storing unit 16, the map information storing unit 17, and the electric power information storing unit 18 are configured with the memory unit. Furthermore, the communication quality calculation apparatus 10 is connected with a display device 19 such as a display. The respective components will be described in detail below.

The acquiring unit 11 acquires information necessary for calculating communication quality from the wireless communication apparatus B, the mobile object control apparatus 20 and the memory unit of itself, and stores the information into the acquired information storing unit 16. Specifically, the acquiring unit 11 acquires a communication quality measurement interval and a frame length of a frame as setting values for wireless communication from the wireless communication apparatus B. The acquiring unit 11 may extract and acquire the abovementioned setting values for wireless communication by traffic monitoring and, as an example, the acquiring unit 11 may perform traffic monitoring to estimate and acquire the setting values from frame intervals and the like. Moreover, the acquiring unit 11 acquires the movement route and movement speed of the mobile object V from the mobile object control apparatus 20. Moreover, the acquiring unit 11 acquires information on a target space where the mobile object may move, which is stored in the map information storing unit 17. Here, the acquiring unit 11 acquires map information representing the entire space (target space) where the mobile object V is set to move, and information for calculating an electric power spectrum at the time of reception of radio waves emitted from the wireless communication apparatus B in the space. As shown in FIG. 3, the electric power spectrum is a spectrum that represents electric power for each frequency of received radio waves in a predetermined region in the space. For example, the information for calculating the electric power spectrum may be an electric power spectrum generated by measuring in advance received radio waves in each of the regions obtained by dividing in advance the inside of the space specified by the map information. Alternatively, the information for calculating the electric power spectrum is information including a reference electric power spectrum and information on the position, structure, installation and so forth of each of the regions in the space, and is information that enables calculation of the electric power spectrum in each of the regions in the space by simulation using a preset calculation formula using the above information. The acquiring unit 11 may acquire the abovementioned information from any information processing apparatus.

The spatial resolution calculating unit 12 (acquiring unit) calculates a spatial resolution that defines a region size for dividing the space into a plurality of regions, based on the measurement interval and frame length that are the setting values for wireless communication acquired as described above and also based on the movement speed of the mobile object, and generates a spatial map in which the space is divided into a plurality of regions based on the spatial resolution. For example, the spatial resolution is calculated so as to satisfy the following condition.

$$Movement distance for one frame \leq spatial resolution \times 2 \leq distance travelled in measurement interval$$

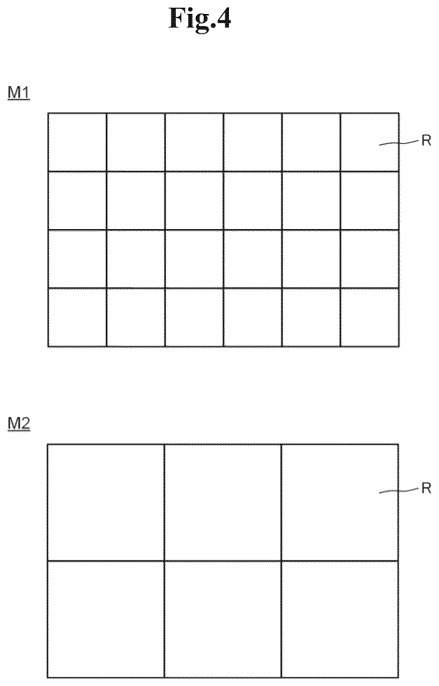

Here, in a case where the frame length of one frame is 1 ms, the movement speed of the mobile object V is 6 km/h (kilometers per hour), and the measurement interval is 40 ms, the movement distance of the mobile object V for one frame is 1.6 mm (millimeters), a distance travelled by the mobile object V in the measurement interval is 66 mm, and the spatial resolution is calculated to be 1 mm, for example. Then, the spatial resolution calculating unit 12 generates a spatial map M1 in which the preset space where the mobile object V moves acquired as described above is divided into regions R each having length and width of 1 mm as shown in the upper diagram of FIG. 4, based on the calculated spatial resolution of 1 mm. Consequently, the spatial map is formed so that the size of one region R is smaller as the movement speed of the mobile object V is slower, and is formed so that the size of one region R is larger as the movement speed of the mobile object V is faster. The lower diagram of FIG. 4 shows a spatial map M2 in a case where the movement speed of the mobile object V is faster than that in the above case and, in this case, the spatial map M2 is formed so that the size of one region R is larger than that in the above case. By thus calculating the spatial resolution, the size of the region R obtained by division is set to a size that is equal to or greater than a range in which the mobile object V moves by frame length, and is set to a size such that the mobile object V moving in the measurement interval spans two or more regions R. In the above example, the measurement interval is 40 ms, and 66 regions R are set within a distance of 66 mm that the mobile object V moves during that interval.

In addition, the spatial resolution calculating unit 12 is not necessarily limited to generating a special map by the abovementioned method. For example, the spatial resolution calculating unit 12 may use a spatial map acquired from the map information storing unit 17, which is prepared by dividing into regions R having a size corresponding to the movement speed of the mobile object V. Moreover, the spatial resolution calculating unit 12 may generate a spatial map in which a plurality of regions are set in advance by changing the size of each region according to the movement speed of the mobile object V.

Moreover, the spatial resolution calculating unit 12 may generate a spatial map by changing a region size of a preset spatial map in which a plurality of regions are set, in accordance with the movement speed of the mobile object V.

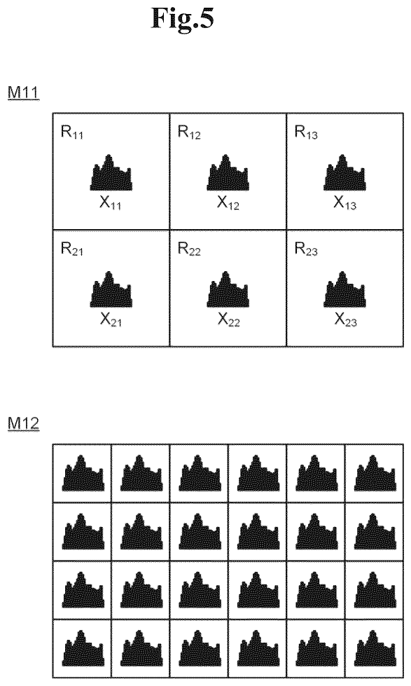

The spectrum calculating unit 13 generates an electric power spectrum that represents electric power for each frequency of received radio waves in each of the regions R within the spatial map generated as described above. As shown in FIG. 3, the electric power spectrum is a graph in which the horizontal axis represents frequency and the vertical axis represents electric power. At this time, the spectrum calculating unit 13 calculates an electric power spectrum for each of the regions R within the spatial map, generates an electric power map in which an electric power spectrum X is associated with each of the regions as shown in FIG. 5, and stores the electric power map in the electric power information storing unit 18. For example, the upper diagram of FIG. 5 shows an electric power map M11 generated by calculating power spectrum R₁₁, R₁₂, . . . for each region R₁₁, R₁₂, . . . . Also, in the case of an electric power map M12 in which the regions are formed smaller as shown in the lower diagram of FIG. 5, the electric power spectrum of each of the regions is calculated and associated.

The spectrum calculating unit 13 uses the information acquired as described above to calculate an electric power spectrum of each of the regions by simulation. For example, information on a reference electric power spectrum within a space is prepared, and the reference power spectrum is used to calculate an electric power spectrum to be estimated for each of the regions by a preset formula based on information such as the position, structure, and installation of each of the regions within the space. Alternatively, the spectrum calculating unit 13 may acquire an electric power spectrum generated by measuring received radio waves in advance in each of the regions obtained by dividing a space in advance, and use the electric power spectrum. Moreover, the spectrum calculating unit 13 may calculate an electric power spectrum of a new region generated by dividing or aggregating the sizes of the regions, from electric power spectrums prepared corresponding to the respective regions within the space. In addition, the spectrum calculating unit 13 may calculate or acquire an electric power spectrum of each of the regions in the space by any method.

The variation intensity calculating unit 14 (variation calculating unit) calculates the degree of variation in communication quality between regions in the spatial map generated as described above, based on a change in electric power spectrum between the regions. At this time, the variation intensity calculating unit 14 may examine a change in electric power spectrum between adjacent regions and calculate the degree of variation in communication quality between the regions, or may examine a change in electric power spectrum between regions located apart with another region therebetween and calculate the degree of variation in communication quality between the regions. Furthermore, the variation intensity calculating unit 14 may also distinguish movement directions between regions, examine a change in electric spectrum between the regions for each movement direction, and calculate the degree of variation in communication quality between the regions. Here, the “degree of variation” in the present application can also be understood as the degree of change, the level of change, the intensity of variation (strength of variation), the magnitude of variation, the level of variation, and the like.

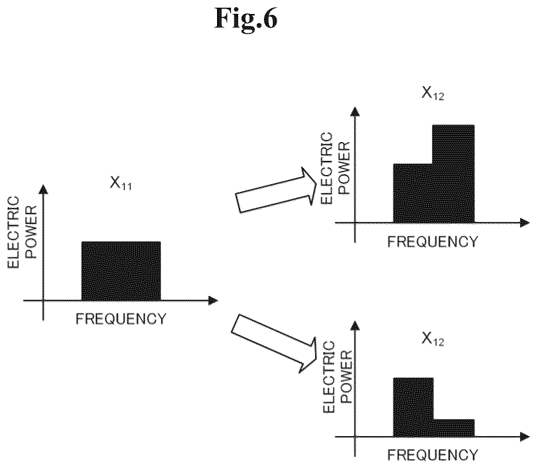

Here, a method for calculating the degree of variation in communication quality will be described using the adjacent regions R₁₁ and R₁₂ of the electric power map M11 shown in the upper diagram of FIG. 5 as an example. FIG. 6 is a simplified diagram showing electric power spectrums X₁₁ and X₁₂ of the regions R₁₁ and R₁₂, respectively. Then, here, a movement direction from the region R₁₁ to the region R₁₂ will be considered. First, in the upper diagram of FIG. 6, electric power of the electric power spectrum X₁₂ in the region R₁₂ has increased from that of the electric power spectrum X₁₁ in the region R₁₁. In this case, since received electric power increases as the mobile object V moves in the movement direction, it is considered that there is no need to consider communication quality. On the other hand, in the lower diagram of FIG. 6, electric power of the electric power spectrum X₁₂ in the region R₁₂ has decreased from that of the electric power spectrum X₁₁ in the region R₁₁. In this case, since received electric power decreases as the mobile object V moves in the movement direction, there is a need to pay attention to deterioration of communication quality. Therefore, in a case where the electric energy of received signals decreases in the movement direction as shown in the lower diagram of FIG. 6, the variation intensity calculating unit 14 calculates the degree of variation in communication quality in the movement direction to become larger. In particular, the variation intensity calculating unit 14 calculates the value of a variation intensity D representing the degree of variation in communication quality in the movement direction so that the value becomes larger as the electric energy of received signals in the movement direction decreases. More specifically, the sum of the quantities of decrease in the electric energy of received signals in the movement direction is calculated as the variation intensity D.

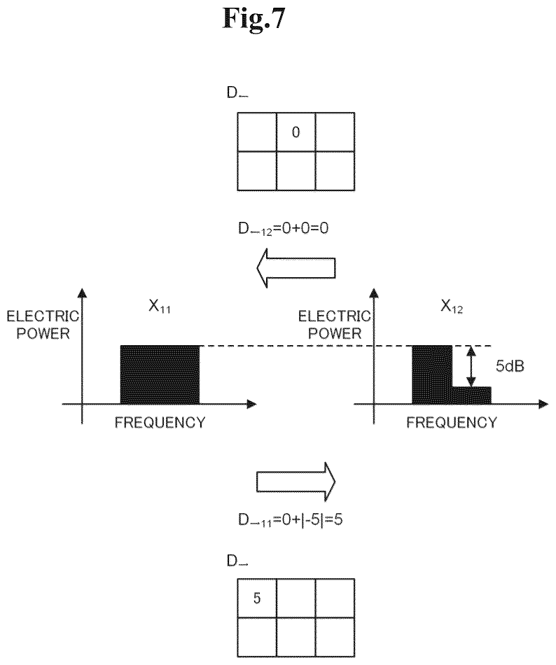

As an example, a case will be given in which electric energy in the electric power spectrum X₁₂ of the region R₁₂ has decreased by 5 dB (decibels) from that in the electric power spectrum X₁₁ of the region R₁₁ as shown in FIG. 7. In this case, a variation intensity D_{→11} in a movement direction from the region R₁₁ to the region R₁₂ (rightward direction in the drawing) can be calculated as 0+|−5|=5. On the other hand, an electric power variation intensity D_{←12} in the opposite movement direction, that is, a movement direction from the region R₁₂ to the region R₁₁ (leftward direction in the drawing) is calculated as 0 because there is no decrease in electric energy. Then, the variation intensity calculating unit 14 generates a variation intensity map in which the calculated variation intensity is associated with each of the regions of the spatial map. At this time, the variation intensity calculating unit 14 generates a variation intensity map for each movement direction (for example, for each of the four directions of upward, downward, leftward, and rightward directions in the spatial map). For example, a variation intensity map D_{←} shown in the upper part of FIG. 7 is a variation intensity map corresponding to the leftward direction, and a variation intensity map D_{→} shown in the lower part of FIG. 7 is a variation intensity map corresponding to the rightward direction.

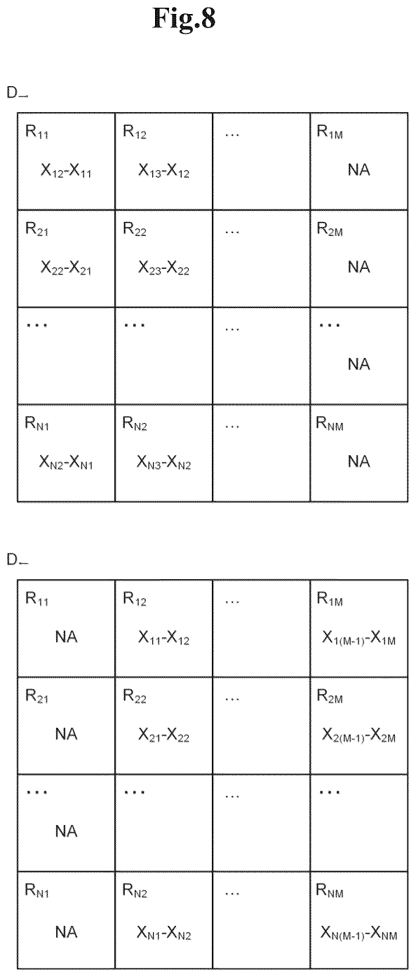

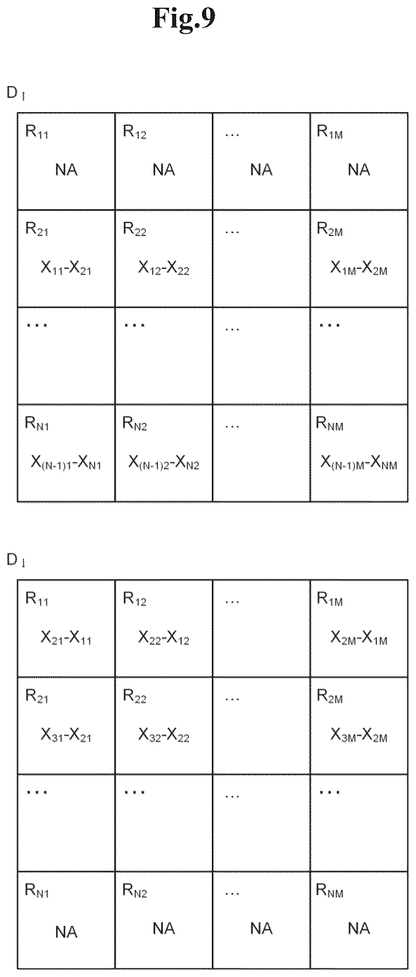

Here, an example of the variation intensity map generated by the variation intensity calculating unit 14 will be described further with reference to FIGS. 8 and 9. The upper diagram of FIG. 8 shows the variation intensity map D_{→} in which the movement direction is rightward. As shown in this variation intensity map D_{→}, for each of the regions R, a variation intensity from the region R to a region R adjacent thereto on the right side is calculated. For example, for the region R₁₁, an electric power decrease quantity (X₁₂−X₁₁) from the region R₁₁ to the region R₁₂ adjacent thereto on the right side is calculated as the variation intensity D_{→11}. In addition, since a region R_{1M} and the like at the right end of the spatial map does not have a region further on the right side, the variation intensity is NA. Here, the inability to calculate the variation intensity will be represented as NA. Then, the variation intensity calculating unit 14 generates a variation intensity map D_{←} with a leftward movement direction as shown in the lower diagram of FIG. 8, a variation intensity map D_{↑} with an upward movement direction as shown in the upper diagram of FIG. 9, and a variation intensity map D_{↓} with a downward movement direction as shown in the lower diagram of FIG. 9.

The output unit 15 (display unit) outputs the value of the variation intensity D of each of the regions R of the spatial map calculated as described above so as to display on the display device 19. At this time, as shown in FIGS. 8 and 9 described above, the output unit 15 may, for each movement direction, associate the variation intensity D with each of the regions R on the spatial map and output so as to display. At this time, the output unit 15 may aggregate a plurality of regions R located in proximity to each other, and also aggregate the variation intensities D of these regions R and output. For example, the output unit 15 may aggregate a plurality of regions R by calculating the average, mode, sum or the like of the variation intensities D corresponding to the plurality of regions R, and output as the variation intensity D of the aggregated regions R. For example, regions D to be aggregated may be set in accordance with a movement distance by one control of the mobile object V and, as one example, two adjacent regions may be aggregated.

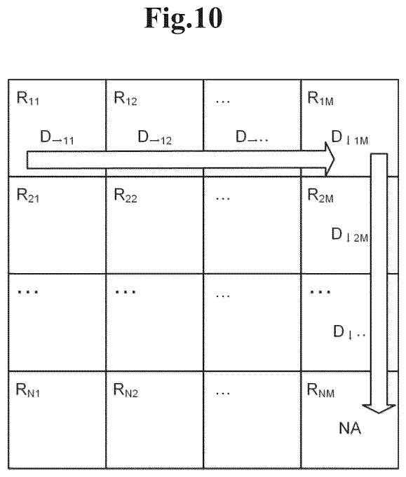

Further, the output unit 15 may output so as to display, along a preset movement route of the mobile object V, the variation intensity D between regions in the movement direction. For example, as shown by arrows in FIG. 10, in a case where the movement route of the mobile object V on the spatial map first goes rightward through regions R₁₁, R₁₂, . . . , R_{1M} and then goes downward through regions R_{1M}, R_{2M}, . . . , R_{NM}, only a variation intensity in each direction of each region R (D_{→11}, D_{→12}, D_{→} . . . , D_{↓1M}, D_{↓2M}, D_{↓} . . . , NA) may be displayed. At this time, as shown in FIG. 10, a variation intensity may be displayed and output in association with the position of the region R on the spatial map, or a variation intensity may be output in vector representation for each movement direction.

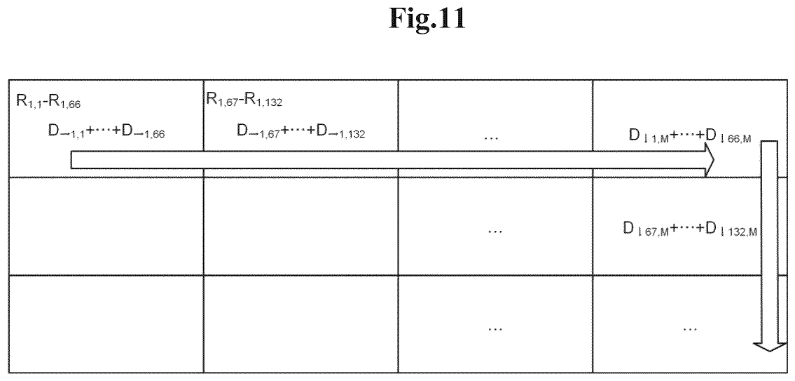

Further, as shown in FIG. 11, the output unit 15 may aggregate a plurality of regions R on the spatial map along the movement route of the mobile object V, and also aggregate the variation intensities D of these regions R to output the average, mode, sum or the like as the variation intensity D of the aggregated regions R. In the example of FIG. 11, the output unit 15 aggregates, in each of the movement directions, 66 regions corresponding to a distance travelled by the mobile object V during the measurement interval, and calculates the sum of the variation intensities D of these regions to aggregate and display.

### Operation

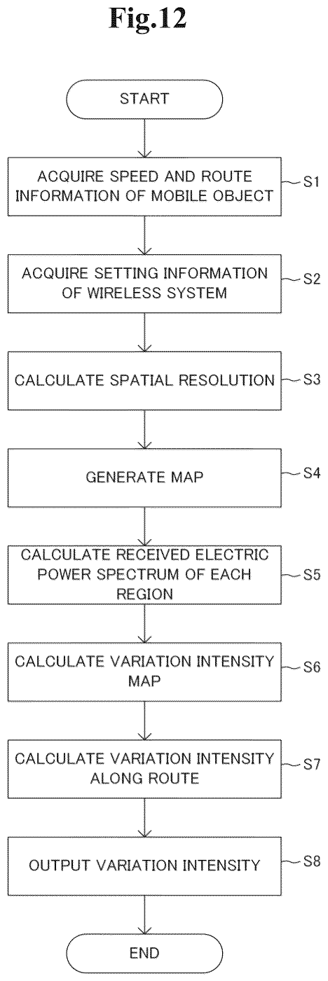

Next, the operation of the abovementioned communication quality calculation apparatus 10 will be described mainly with reference to a flowchart of FIG. 12.

The communication quality calculation apparatus 10 acquires information necessary for calculating communication quality. For example, the communication quality calculation apparatus 10 acquires the movement route and movement speed of the mobile object V from the mobile object control apparatus 20 (step S1). Moreover, the communication quality calculation apparatus acquires the communication quality measurement interval and the frame length of a frame as setting values for wireless communication from the wireless communication apparatus B (step S2). Furthermore, the communication quality calculation apparatus 10 acquires map information representing the entire space where the mobile object V is set to move, and information for calculating an electric power spectrum at the time of receiving radio waves emitted from the wireless communication apparatus B in the space.

Next, the communication quality calculation apparatus 10 calculates a spatial resolution that defines a region size for dividing the space into a plurality of regions, using the information acquired as described above (step S3). For example, the communication quality calculation apparatus 10 calculates the spatial resolution so that one region R is smaller as the movement speed of the mobile object V is slower, based on the movement speed of the mobile object V and the interval for measurement of communication quality by the wireless communication apparatus B. Then, the communication quality calculation apparatus 10 generates the spatial map M1 in which the space is divided into a plurality of regions R as shown in FIG. 4 based on the calculated spatial resolution (step S4).

Next, the communication quality calculation apparatus 10 generates an electric power spectrum that represents electric power for each frequency of received radio waves in the each of the regions R within the spatial map (step S5). For example, the electric power spectrum can be expressed using a graph in which the horizontal axis represents frequency and the vertical axis represents electric power as shown in FIG. 3. For example, the communication quality calculation apparatus 10 calculates the electric power spectrum in each region by simulation, using a prepared formula for calculating electric power spectrum and information such as the position and structure of each region within the space. Then, as shown in FIG. 5, the communication quality calculation apparatus 10 calculates a variation intensity D, which is the degree of variation in communication quality between regions corresponding to a change in electric power spectrum between the regions, based on the electric power spectrum calculated for each of the regions within the spatial map (step S6). At this time, the communication quality calculation apparatus 10 distinguishes movement directions between regions, examines a change in spectrum between the regions for each of the movement directions, and calculates the variation intensity D of communication quality between the regions. In particular, the communication quality calculation apparatus 10 calculates so that the value of the variation intensity D becomes larger as received electric energy decreases in the movement direction between the regions. Thus, the communication quality calculation apparatus 10 generates a variation intensity map in which the variation intensities D of the respective regions R are set for each of the movement directions as shown in FIGS. 7 and 8.

Next, the communication quality calculation apparatus 10 calculates, along the movement route of the mobile object V, the variation intensity D between regions in the movement direction (step S7). For example, the communication quality calculation apparatus 10 may simply extract the variation intensity D of each of the regions in the movement direction on the movement route as shown in FIG. 10, or may aggregate the variation intensities D of a plurality of regions in the movement direction as shown in FIG. 11. Then, the communication quality calculation apparatus 10 outputs the variation intensity D on the movement route so as to display on the display device 19 (step S8). At this time, the communication quality calculation apparatus 10 may display the variation intensities D together with the respective regions R of the spatial map as shown in FIGS. 10 and 11, or may display an enumeration of only the values of the variation intensities D along the route. In addition, the communication quality calculation apparatus 10 may output so as to simply display a variation intensity map for each movement direction in the entire space as shown in FIGS. 8 and 9, without considering the movement route of the mobile object V.

As described above, according to this example embodiment, it is possible to accurately predict communication quality in a region where the mobile object V may move during the communication quality measurement interval, and it is possible to appropriately control the mobile object V with reference to the communication quality. Furthermore, by calculating the degree of variation in communication quality for each movement direction between regions, it is possible to accurately predict communication quality in consideration of the movement direction of the mobile object V, and it is thereby possible to increase the stability of control of the mobile object V.

### Second Example Embodiment

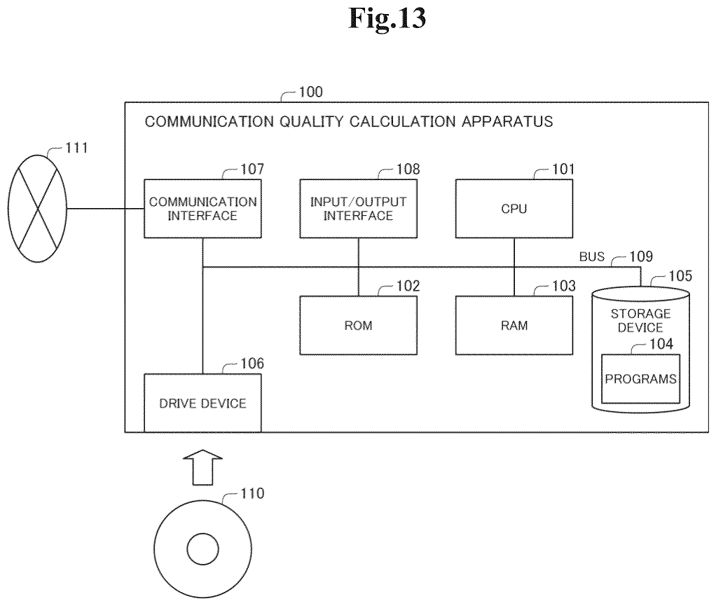

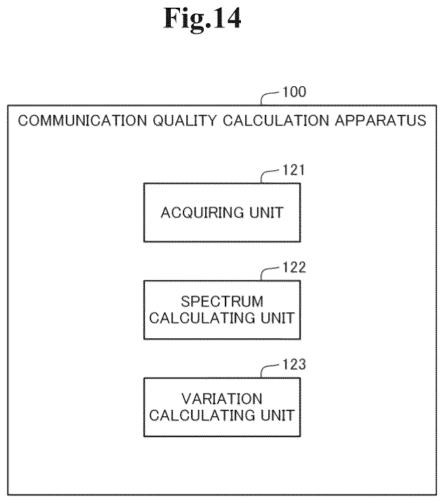

Next, a second example embodiment of the present disclosure will be described with reference to FIGS. 13 and 14. FIGS. 13 and 14 are block diagrams showing the configuration of a communication quality calculation apparatus in the second example embodiment. In this example embodiment, the overview of the configuration of the communication quality calculation apparatus described in the above example embodiment is shown.

First, the hardware configuration of a communication quality calculation apparatus 100 in this example embodiment will be described with reference to FIG. 13. The communication quality calculation apparatus 100 is configured with a general information processing apparatus and has, as an example, the following hardware configuration including:
a CPU (Central Processing Unit) 101 (arithmetic logic unit);
a ROM (Read Only Memory) 102 (memory unit);
a RAM (Random Access Memory) 103 (memory unit);
programs 104 loaded to the RAM 103;
a storage device 105 storing the programs 104;
a drive device 106 that reads from and writes into a storage medium 110 outside the information processing apparatus;
a communication interface 107 connected to a communication network 111 outside the information processing apparatus;
an input/output interface 108 that inputs and outputs data; and
a bus 109 connecting the respective components.

Then, by acquisition and execution of the programs 104 by the CPU 101, the communication quality calculation apparatus 100 can structure and include an acquiring unit 121, a spectrum calculating unit 122 and a variation calculating unit 123 shown in FIG. 9. The programs 104 are, for example, stored in the storage device 105 or the ROM 102 in advance, and loaded to the RAM 103 and executed by the CPU 101 as necessary. Moreover, the programs 104 may be provided to the CPU 101 via the communication network 111, or the programs 104 may be stored in advance in the storage medium 110 and read out by the drive device 106 and provided to the CPU 101. However, the acquiring unit 121, the spectrum calculating unit 122 and the variation calculating unit 123 described above may be structured by dedicated electronic circuits for realizing such means.

FIG. 3 shows an example of the hardware configuration of the information processing apparatus serving as the communication quality calculation apparatus 100, and the hardware configuration of the information processing apparatus is not limited to the abovementioned case. The information processing apparatus may be configured with part of the abovementioned configuration, for example, not having the drive device 106. Moreover, the information processing apparatus may use a GPU (Graphic Processing Unit), a DSP (Digital Signal Processor), an MPU (Micro Processing Unit), an FPU (Floating point number Processing Unit), a PPU (Physics Processing Unit), a TPU (Tensor Processing Unit), a quantum processor, a microcontroller, or a combination thereof, instead of the abovementioned CPU.

The abovementioned acquiring unit 121 acquires a spatial map having a plurality of regions in which a target space where a mobile object may move is divided by a size corresponding to a movement speed of the mobile object. The special map is formed by dividing a space where a mobile object may move into a plurality of regions by a spatial resolution corresponding to a movement speed.

The abovementioned spectrum calculating unit 22 generates a spectrum representing electric power for each frequency of received radio waves in each region in the spatial map, based on preset information. For example, the spectrum is generated by simulation in accordance with a characteristic of the received radio waves and a characteristic of each region in the space.

The variation calculating unit 123 calculates, based on a change in spectrum between the regions in the spatial map, a degree of variation in communication quality between the regions. For example, the variation calculating unit 123 calculates a degree that communication quality decreases in a movement direction between the regions.

Configured as described above, the present disclosure enables accurate prediction of communication quality in respective regions within the spatial map where the mobile object may move during the communication quality measurement interval, for example, decrease in communication quality due to fading or the like. Consequently, it is possible to appropriately control the mobile object in consideration of communication quality in the movement direction of the mobile object.

The abovementioned program can be stored using various types of non-transitory computer-readable mediums and provided to the computer. Non-transitory computer-readable mediums include various types of tangible storage mediums. Examples of non-transitory computer-readable mediums include a magnetic recording medium (e.g., flexible disk, magnetic tape, hard disk drive), a magneto-optical recording medium (e.g., magneto-optical disk), a CD-ROM (Read Only Memory), a CD-R, a CD-R/W, and a semiconductor memory (e.g., mask ROM, PROM (Programmable ROM), EPROM (Erasable PROM), flash ROM, and RAM (Random Access Memory)). The program may also be provided to the computer by various types of transitory computer-readable mediums. Examples of transitory computer-readable medium include electrical signals, optical signals, and electromagnetic waves. Transitory computer-readable medium can provide the program to the computer via a wired communication path such as an electric wire or an optical fiber, or via a wireless communication path.

Although the present disclosure has been described above with reference to the example embodiments and so forth, the present disclosure is not limited to the above example embodiments. The configuration and details of the present disclosure can be changed in various manners that can be understood by one skilled in the art within the scope of the present disclosure. Moreover, at least one or more of the functions of the acquiring unit 121, the spectrum calculating unit 122 and the variation calculating unit 123 described above may be executed by an information processing apparatus installed anywhere on the network and connected, that is, may be executed by so-called cloud computing.

### SUPPLEMENTARY NOTES

The whole or part of the example embodiments disclosed above can be described as the following supplementary notes. Below, the overview of the configurations of a communication quality calculation method, a communication quality calculation apparatus, and a program according to the present invention will be described. However, the present invention is not limited to the following configurations.

### Supplementary Note 1

A communication quality calculation method comprising:
acquiring a spatial map having a plurality of regions obtained by dividing a target space in which a mobile object will move by a size corresponding to a movement speed of the mobile object;
generating a spectrum representing electric power for each frequency of received radio waves in each of the regions within the spatial map based on preset information; and
calculating, based on a change in the spectrum between the regions within the spatial map, a degree of variation in communication quality between the regions.

### Supplementary Note 2

The communication quality calculation method according to Supplementary Note 1, comprising
calculating, for each direction of movement between the regions, the degree of variation in communication quality based on the change in the spectrum in the direction of movement.

### Supplementary Note 3

The communication quality calculation method according to Supplementary Note 2, comprising
calculating, based on a change in electric energy of the received radio waves represented by the spectrum in the direction of movement between the regions, the degree of variation in communication quality in the direction of movement between the regions.

### Supplementary Note 4

The communication quality calculation method according to Supplementary Note 3, comprising
in a case where the electric energy decreases in the direction of movement between the regions, calculating the degree of variation in communication quality in the direction of movement so that the degree of variation becomes larger.

### Supplementary Note 5

The communication quality calculation method according to Supplementary Note 1, comprising
acquiring the spatial map by dividing the target space into the plurality of regions by resolution that defines the size of the region based on the movement speed and generating the spatial map.

### Supplementary Note 6

The communication quality calculation method according to Supplementary Note 5, comprising
acquiring the spatial map by dividing the target space into the plurality of regions by resolution that defines the size of the region based on an interval for measuring communication quality in the target space and the movement speed and generating the spatial map.

### Supplementary Note 7

The communication quality calculation method according to Supplementary Note 1, comprising
displaying on a display device together with the spatial map, the degree of variation in communication quality between the regions in correspondence with a position of the region on the spatial map.

### Supplementary Note 8

The communication quality calculation method according to Supplementary Note 2, comprising
displaying on a display device together with the spatial map, the degree of variation in communication quality in the direction of movement between the regions corresponding to a preset direction of movement of the mobile body.

### Supplementary Note 9

A communication quality calculation method comprising:
calculating a degree of variation in communication quality between regions based on a change between the regions of a spectrum, the spectrum representing electric power for each frequency of received radio waves in each of the regions within a spatial map, the spatial map having a plurality of regions obtained by dividing a target space in which a mobile object will move by a size corresponding to a movement speed of the mobile object; and
displaying the degree of variation on a display device.

### Supplementary Note 10

A communication quality calculation apparatus comprising:
an acquiring unit that acquires a spatial map having a plurality of regions obtained by dividing a target space in which a mobile object will move by a size corresponding to a movement speed of the mobile object;
a spectrum calculating unit that generates a spectrum representing electric power for each frequency of received radio waves in each of the regions within the spatial map based on preset information; and
a variation calculating unit that calculates, based on a change in the spectrum between the regions within the spatial map, a degree of variation in communication quality between the regions.

### Supplementary Note 11

The communication quality calculation apparatus according to Supplementary Note 10, wherein
the variation calculating unit calculates, for each direction of movement between the regions, the degree of variation in communication quality based on the change in the spectrum in the direction of movement.

### Supplementary Note 12

The communication quality calculation apparatus according to Supplementary Note 11, wherein
the variation calculating unit calculates, based on a change in electric energy of the received radio waves represented by the spectrum in the direction of movement between the regions, the degree of variation in communication quality in the direction of movement between the regions.

### Supplementary Note 13

The communication quality calculation apparatus according to Supplementary Note 12, wherein
in a case where the electric energy decreases in the direction of movement between the regions, the variation calculating unit calculates the degree of variation in communication quality in the direction of movement so that the degree of variation becomes larger.

### Supplementary Note 14

The communication quality calculation apparatus according to Supplementary Note 10, wherein
the acquiring unit acquires the spatial map by dividing the target space into the plurality of regions by resolution that defines the size of the region based on the movement speed and generating the spatial map.

### Supplementary Note 15

The communication quality calculation apparatus according to Supplementary Note 14, wherein
the acquiring unit acquires the spatial map by dividing the target space into the plurality of regions by resolution that defines the size of the region based on an interval for measuring communication quality in the target space and the movement speed and generating the spatial map.

### Supplementary Note 16

The communication quality calculation apparatus according to Supplementary Note 10, comprising
a display unit that displays on a display device together with the spatial map, the degree of variation in communication quality between the regions in correspondence with a position of the region on the spatial map.

### Supplementary Note 17

The communication quality calculation apparatus according to Supplementary Note 11, comprising
a display unit that displays on a display device together with the spatial map, the degree of variation in communication quality in the direction of movement between the regions corresponding to a preset direction of movement of the mobile body.

### Supplementary Note 18

A communication quality calculation apparatus comprising:
a calculating unit that calculates a degree of variation in communication quality between regions based on a change between the regions of a spectrum, the spectrum representing electric power for each frequency of received radio waves in each of the regions within a spatial map, the spatial map having a plurality of regions obtained by dividing a target space in which a mobile object will move by a size corresponding to a movement speed of the mobile object; and
a display unit that displays the degree of variation on a display device.

### Supplementary Note 19

A computer-readable storage medium storing a program comprising instructions for causing a computer to execute processes to:
acquire a spatial map having a plurality of regions obtained by dividing a target space in which a mobile object will move by a size corresponding to a movement speed of the mobile object;
generate a spectrum representing electric power for each frequency of received radio waves in each of the regions within the spatial map based on preset information; and
calculate, based on a change in the spectrum between the regions within the spatial map, a degree of variation in communication quality between the regions.

### REFERENCE SIGNS LIST

10 communication quality calculation apparatus
11 acquiring unit
12 spatial resolution calculating unit
13 spectrum calculating unit
14 variation intensity calculating unit
15 output unit
16 acquired information storing unit
17 map information storing unit
18 electric power information storing unit
19 display device
20 mobile object control apparatus
B wireless communication apparatus
V mobile object
100 communication quality calculation apparatus
101 CPU
102 ROM
103 RAM
104 programs
105 storage device
106 drive device
107 communication interface
108 input/output interface
109 bus
110 storage medium
111 communication network
121 acquiring unit
122 spectrum calculating unit
123 variation calculating unit

What is claimed is:

1. A communication quality calculation method comprising:
acquiring a spatial map having a plurality of regions obtained by dividing a target space in which a mobile object will move by a size corresponding to a movement speed of the mobile object;
generating a spectrum representing electric power for each frequency of received radio waves in each of the regions within the spatial map based on preset information; and
calculating, based on a change in the spectrum between the regions within the spatial map, a degree of variation in communication quality between the regions.

2. The communication quality calculation method according to claim 1, comprising
calculating, for each direction of movement between the regions, the degree of variation in communication quality based on the change in the spectrum in the direction of movement.

3. The communication quality calculation method according to claim 2, comprising
calculating, based on a change in electric energy of the received radio waves represented by the spectrum in the direction of movement between the regions, the degree of variation in communication quality in the direction of movement between the regions.

4. The communication quality calculation method according to claim 3, comprising
in a case where the electric energy decreases in the direction of movement between the regions, calculating the degree of variation in communication quality in the direction of movement so that the degree of variation becomes larger.

5. The communication quality calculation method according to claim 1, comprising
acquiring the spatial map by dividing the target space into the plurality of regions by resolution that defines the size of the region based on the movement speed and generating the spatial map.

6. The communication quality calculation method according to claim 5, comprising
acquiring the spatial map by dividing the target space into the plurality of regions by resolution that defines the size of the region based on an interval for measuring communication quality in the target space and the movement speed and generating the spatial map.

7. The communication quality calculation method according to claim 1, comprising
displaying on a display device together with the spatial map, the degree of variation in communication quality between the regions in correspondence with a position of the region on the spatial map.

8. The communication quality calculation method according to claim 2, comprising
displaying on a display device together with the spatial map, the degree of variation in communication quality in the direction of movement between the regions corresponding to a preset direction of movement of the mobile body.

9. A communication quality calculation method comprising:
calculating a degree of variation in communication quality between regions based on a change between the regions of a spectrum, the spectrum representing electric power for each frequency of received radio waves in each of the regions within a spatial map, the spatial map having a plurality of regions obtained by dividing a target space in which a mobile object will move by a size corresponding to a movement speed of the mobile object; and
displaying the degree of variation on a display device.

10. A communication quality calculation apparatus comprising:
at least one memory configured to store instructions; and
at least one processor configured to execute the instructions to:
acquire a spatial map having a plurality of regions obtained by dividing a target space in which a mobile object will move by a size corresponding to a movement speed of the mobile object;
generate a spectrum representing electric power for each frequency of received radio waves in each of the regions within the spatial map based on preset information; and
calculate, based on a change in the spectrum between the regions within the spatial map, a degree of variation in communication quality between the regions.

11. The communication quality calculation apparatus according to claim 10, wherein the at least one processor is configured to execute the instructions to
calculate, for each direction of movement between the regions, the degree of variation in communication quality based on the change in the spectrum in the direction of movement.

12. The communication quality calculation apparatus according to claim 11, wherein the at least one processor is configured to execute the instructions to
calculate, based on a change in electric energy of the received radio waves represented by the spectrum in the direction of movement between the regions, the degree of variation in communication quality in the direction of movement between the regions.

13. The communication quality calculation apparatus according to claim 12, wherein the at least one processor is configured to execute the instructions to
in a case where the electric energy decreases in the direction of movement between the regions, calculate the degree of variation in communication quality in the direction of movement so that the degree of variation becomes larger.

14. The communication quality calculation apparatus according to claim 10, wherein the at least one processor is configured to execute the instructions to
acquire the spatial map by dividing the target space into the plurality of regions by resolution that defines the size of the region based on the movement speed and generating the spatial map.

15. The communication quality calculation apparatus according to claim 14, wherein the at least one processor is configured to execute the instructions to
acquire the spatial map by dividing the target space into the plurality of regions by resolution that defines the size of the region based on an interval for measuring communication quality in the target space and the movement speed and generating the spatial map.

16. The communication quality calculation apparatus according to claim 10, wherein the at least one processor is configured to execute the instructions to
display on a display device together with the spatial map, the degree of variation in communication quality between the regions in correspondence with a position of the region on the spatial map.

17. The communication quality calculation apparatus according to claim 11, wherein the at least one processor is configured to execute the instructions to
display on a display device together with the spatial map, the degree of variation in communication quality in the direction of movement between the regions corresponding to a preset direction of movement of the mobile body.

18-19. (canceled)
